(19) United States
(12) Patent Application Publication
(10) Pub. No.: US 2018/0269157 A1
(43) Pub. Date: Sep. 20, 2018

(54) WIRING, SEMICONDUCTOR DEVICE AND NAND FLASH MEMORY

(71) Applicant: Kabushiki Kaisha Toshiba, Minato-ku (JP)

(72) Inventors: Masayuki KATAGIRI, Tsukuba (JP); Tatsuro SAITO, Kawasaki (JP); Tadashi SAKAI, Yokohama (JP); Hisao MIYAZAKI, Yokohama (JP)

(73) Assignee: Kabushiki Kaisha Toshiba, Minato-ku (JP)

(21) Appl. No.: 15/693,643

(22) Filed: Sep. 1, 2017

(30) Foreign Application Priority Data
Mar. 17, 2017 (JP) 2017-052545

(51) Int. Cl. H01L 23/532; H01L 27/11524; H01L 27/1157

(52) U.S. Cl. CPC H01L 23/53276; H01L 27/1157; H01L 27/11524

(57) ABSTRACT

A wiring of an embodiment includes: a multilayer graphene including graphene sheets laminated in a first direction, the multilayer graphene extended in a second direction regarded as a longitudinal direction that intersects with the first direction; a first metal part in direct contact with the multilayer graphene; a second metal part spaced apart from the first metal part in the second direction, the second metal part in direct contact with the multilayer graphene; a first conductive part disposed on the multilayer graphene in the first direction, and electrically connected to the multilayer graphene with the first metal part interposed therebetween; and a second conductive part disposed on the multilayer graphene in the first direction, and electrically connected to the multilayer graphene with the second metal part interposed therebetween.

### CROSS-REFERENCE TO RELATED APPLICATION

This application is based upon and claims the benefit of priority from Japanese Patent Application No. 2017-052545, filed on Mar. 17, 2017; the entire contents of which are incorporated herein by reference.

### FIELD

Embodiments described herein relate to a wiring, a semiconductor device, and NAND flash memory.

### BACKGROUND

With miniaturization and multilayering of LSI (Large-Scale Integration) and 3D memories, increased wiring delays have become serious problems with metal wirings. In order to reduce the wiring delays, it is important to reduce the wiring resistances and the inter-wiring capacitance. For lowering the resistances of the wirings, for example, low-resistance materials such as Cu have been put to practical use. However, Cu wirings also have problems such as reliability degradation due to stress migration and electromigration, and an increase in electric resistivity due to size effect, and wiring materials have been required which are low in resistance and excellent in resistance to current density. As next-generation wiring materials that can be expected to be low in resistance and high in reliability, the application of carbon-based materials such as carbon nanotubes and graphene, which have excellent physical properties such as high resistance to current density, electric conduction property, and thermal conductivity, has been attracting attention.

In multilayer wiring structures, layers are connected by via wirings. In the case of multilayer graphene wirings, a method of connecting to side edges in the longitudinal direction of all of the multilayer graphene layers with the use of a conductive member is conceivable for connection to via wirings. However, the electric conduction through the graphene is discontinuous at the connection parts with the via wirings, and the contribution of the resistance component of the conductive film is made non-negligible.

### BRIEF DESCRIPTION OF THE DRAWINGS

FIG. 1 is a perspective pattern diagram of a wiring according to an embodiment;

FIGS. 2A, 2B, 2C, 2D, 2E, and 2F are cross-sectional pattern diagrams of wirings according to an embodiment;

FIGS. 3A and 3B are top pattern diagrams of wirings according to an embodiment;

FIG. 4 is a perspective pattern diagram of a wiring according to an embodiment;

FIG. 5 is a perspective pattern diagram of a wiring according to an embodiment;

FIG. 6 is a perspective pattern diagram of a semiconductor device according to an embodiment; and

FIG. 7 is a cross-sectional pattern diagram of a semiconductor device according to an embodiment.

### DETAILED DESCRIPTION

A wiring of an embodiment includes: a multilayer graphene including graphene sheets laminated in a first direction, the multilayer graphene extended in a second direction regarded as a longitudinal direction that intersects with the first direction; a first metal part in direct contact with the multilayer graphene; a second metal part spaced apart from the first metal part in the second direction, the second metal part in direct contact with the multilayer graphene; a first conductive part disposed on the multilayer graphene in the first direction, and electrically connected to the multilayer graphene with the first metal part interposed therebetween; and a second conductive part disposed on the multilayer graphene in the first direction, and electrically connected to the multilayer graphene with the second metal part interposed therebetween. The first conductive part and the second conductive part are electrically connected with the first metal part, the multilayer graphene, the second metal part interposed therebetween. A length L1 of the multilayer graphene in the second direction is larger than a length L2 between the first metal part and the second metal part.

### Embodiment 1

Embodiments of the present disclosure will be described below with reference to the drawings. Elements with the same reference numerals assigned thereto indicate like elements. It is to be noted that the drawings are schematic or conceptual, and the relationship between the thickness and width of each part, the coefficient of the ratio in size between the respective parts, and the like are not necessarily equal to those of actual objects. Even in the case of representing the same parts, the respective dimensions and coefficients of ratios are shown differently depending on the drawings in some cases.

A wiring according to Embodiment 1 has a multilayer graphene, a first metal part, a second metal part, a first conductive part, and a second conductive part. The multilayer graphene has a connection structure that is not discontinuous at connection parts with via wirings.

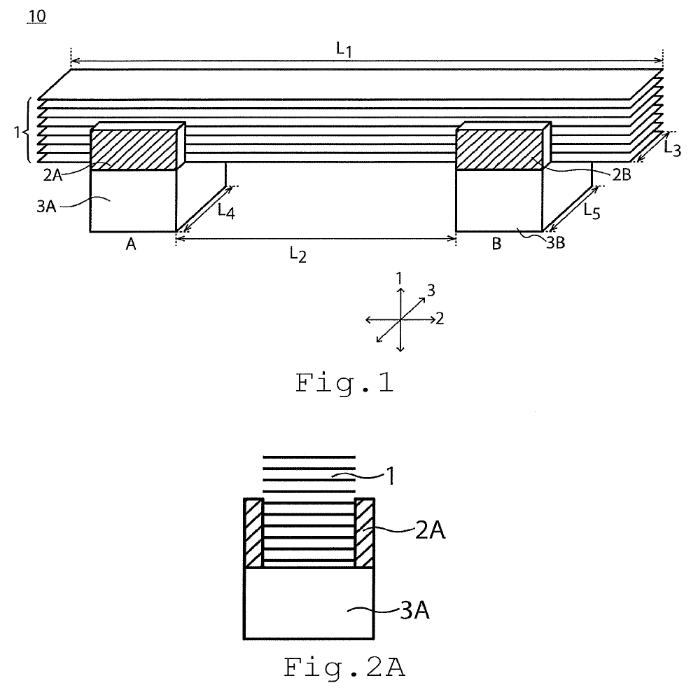

FIG. 1 shows a perspective view of a wiring 10 according to Embodiment 1.

The graphene wiring structure 10 in FIG. 1 has a multilayer graphene 1, a first metal part 2A in contact with the multilayer graphene 1, a second metal part 2B in contact with the multilayer graphene 1, a first conductive part 3A in direct contact with the first metal part 2A, and a second conductive part 3B indirect contact with the second metal part 2B. The perspective view of FIG. 1 shows the structure of a part of the wiring.

The multilayer graphene 1 includes laminated graphene sheets. The multilayer graphene 1 is electrically connected to a via wiring A and a via wiring B. More specifically, the multilayer graphene 1 includes a planar graphene sheet. The planar graphene sheet may be a monoatomic layer composed of carbon atoms, or may be a monoatomic layer of carbon atoms and some carbon atoms that form bonds with oxygen or nitrogen atoms or the like. The planar graphene sheet includes no graphene sheet rolled like carbon nanotubes or the like. The planar graphene sheet has, for example, a sheet-like structure with an atomic layer spread on a plane surface of a graphene nanoribbon or the like. The planar graphene sheet may include defects. The planar graphene sheet may have polycrystalline graphene.

The laminating direction of the multilayer graphene 1 is referred to as a first direction. The length of the multilayer graphene 1 in the first direction is the height of the multilayer graphene 1. The multilayer graphene 1 and the graphene sheet extend in a second direction which is the wiring length direction. The second direction is the longitudinal direction of the multilayer graphene 1 and the graphene sheet. The length of the multilayer graphene 1 in the second direction is denoted by L1. The first direction intersects with the second direction. The first direction is preferably orthogonal to the second direction. The multilayer graphene 1 and the graphene sheet extend in a third direction which is the wiring width direction. The third direction is the transverse direction of the multilayer graphene 1 and the graphene sheet. The length (width) of the multilayer graphene 1 in the third direction is denoted by L3. The third direction intersects with the first direction and the second direction. The third direction is preferably orthogonal to the first direction and orthogonal to the second direction. The numbers of the respective directions are only shown in the figure.

The multilayer graphene 1 is directly connected to the metal part. More specifically, a part of the lamination surface of the multilayer graphene 1 is directly and electrically connected to the metal part. Depending on the connection with the metal part, the multilayer graphene 1 is not discontinuous. For example, in the case of a wiring that has two multilayer graphenes connected by a metal part, the multilayer graphenes are made discontinuous by the connections between the multilayer graphenes and the metal part. The metal part has no influence on the wiring resistance of the individual multilayer graphene itself. However, considering the conduction between the two multilayered graphene, the metal part substantially serves as a resistance. Then, although the use of graphene as a conductive material lowers the resistance of the graphene portion, the existence of the metal part which substantially serves as a resistance makes it difficult to lower the resistance as expected by graphene as a whole. According to the embodiment, since the multilayer graphene 1 is not made discontinuous, there is a conductive line formed by the continuous multilayer graphene 1 from the starting point of the wiring of the multilayer graphene to the end point thereof.

The number n of planar graphene sheets laminated is not particularly limited, and is preferably 10 or more and 100 or less, for example. The distance in the stacking direction of the multilayer graphene 1 is the height of the multilayer graphene 1. The height of the multilayer graphene 1 is, for example, 3 nm or more and 35 nm or less. There may be an interlayer substance between the layers of the multilayer graphene 1, that is, between the opposed planar graphene sheets. In a case where there is an interlayer substance, the interlayer distance of the multilayer graphene 1 ranges from 0.335 nm to, for example, 0.5 nm or more and 1 nm or less, and thus, in the case of including an interlayer substance between the layers, the height of the multilayer graphene 1 is 5 nm or more and 100 nm or less. The interlayer substance is preferably a substance that contributes to lowering the resistance of the multilayer graphene 2 and lowering the capacity, and is, for example, a metal halide such as iron chloride or molybdenum chloride, or halogen, but is not particularly limited thereto.

The length L3 in the third direction, which is the width of the multilayer graphene 1, is preferably 10 nm or less, more preferably 3 nm or more and 10 nm or less. While a metal wiring tends to be large in conductor loss when the line width is 10 nm or less, the wiring according to the embodiment is preferably small in conductor loss even with a line width of 10 nm or less. The height, the length, the wiring width, and the like of the multilayer graphene 1 are obtained by observation with a transmission electron microscope or the like.

The length L1 of the multilayer graphene 1 is 1 μm or more, but is not limited thereto.

The ratio (L1/L3) between the length L3 in the third direction, which is the width of the multilayer graphene 1, and the length L1 in the second direction of the multilayer graphene 1, which is the length of the multilayer graphene 1, is preferably 100 or more and 100,000,000 or less. If the ratio is excessively low, the distance between the conductive parts will be excessively low, causing leakage and the like, which is not preferable. On the other hand, if the ratio is excessively high, it will be difficult to form a fine-width long-distance wiring without discontinuity, which is not preferable.

Graphene has two kinds of edges, a zigzag edge and an armchair edge. When the electric conduction direction is the zigzag direction, the graphene is low in resistance. Conversely, when the electric conduction direction is the armchair direction, the graphene becomes a semiconductor. When the zigzag direction is oriented in the second direction which is the electric conduction direction, the wiring is low in resistance, which is preferable. Therefore, the graphene sheet of the multilayer graphene 1 preferably includes, at a side edge thereof in the second direction, a zigzag edge. In addition, the graphene sheet of the multilayer graphene 1 preferably includes, at a side edge thereof in the third direction, an armchair edge.

The first metal part 2A and the first conductive part 3A constitute the first via wiring A. The first metal part 2A is in direct contact with a part of the lamination surface of the multilayer graphene 1. The first conductive part 3A is in contact with the multilayer graphene 1 in the first direction. The first conductive part 3A is electrically connected to the multilayer graphene 1 via the first metal part 2A.

The second metal part 2B and the second conductive part 3B constitute the second via wiring B. The second metal part 2B is in direct contact with a part of the lamination surface of the multilayer graphene 1. The second conductive part 3B is in contact with the multilayer graphene 1 in the first direction. The second conductive part 3B is electrically connected to the multilayer graphene 1 via the second metal part 2B.

The first metal part 2A is in direct contact with at least a part of the lamination surface of the multilayer graphene 1. The first metal part 2A is spaced from the second metal part 2B in the second direction. The second metal part 2B is in direct contact with a part of the lamination surface of the multilayer graphene 1. The lamination surface of the multilayer graphene 1 is an end surface in the third direction of the multilayer graphene 1. The end surface includes the edge side of the graphene sheet. Specifically, the side edge of the graphene sheet of the multilayer graphene 1 in the third direction partially is in direct contact the first metal part 2A and the second metal part 2B. From the above-described viewpoint of conductivity, the first metal part 2A and the second metal part 2B are preferably in direct contact with the zigzag edge of the graphene sheet of the multilayer graphene 1.

Among the graphene sheets of the multilayer graphene 1, the side edge of, in the third direction, the graphene sheet closest to the first conductive part 3A (closest to the lowermost layer) in the first direction partially is in direct contact with the first metal part 2A. In addition, among the graphene sheets of the multilayer graphene 1, the side edge of the graphene sheet closest to the second conductive part 3B in the first direction partially is in direct contact with the second metal part 2B. The larger the number of the graphene sheets of the multilayer graphene 1 in direct contact with the first metal part 2A, the more favorable the contact property between the first metal part 2A and the multilayer graphene 1, which is preferable. Likewise, the larger the number of graphene sheets of the multilayer graphene 1 in direct contact with the second metal part 2B, the more favorable the contact property between the second metal part 2B and the multilayer graphene 1, which is preferable. Therefore, the first metal part 2A and the second metal part 2B preferably are in direct contact with two or more layers of graphene sheets. In addition, when the number of graphene sheets in the multilayer graphene 1 laminated is denoted by n, the first metal part 2A and the second metal part 2B preferably is in direct contact with n/2 or more layers of graphene sheets (side edges in the third direction from the graphene sheet located closest to the first conductive part 2A in the first direction to at least the n/2-th graphene sheet is in direct contact with the first metal part 2A, side edges in the third direction from the graphene sheet located closest to the second conductive part 2B in the first direction to at least the n/2-th graphene sheet is partially in direct contact with the second metal part 2B). The first metal part 2A and the second metal part 2B more preferably are in direct contact with the n layers of graphene sheets (side edges in the third direction from the graphene sheet located closest to the first conductive part 2A in the first direction to at least the n-th graphene sheet is in direct contact with the first metal part 2A, side edges in the third direction from the graphene sheet located closest to the second conductive part 2B in the first direction to at least the n-th graphene sheet is partially in direct contact with the second metal part 2B).

When the connection form is different, the contact property is affected accordingly. Therefore, the first metal part 2A and the multilayer graphene 1 preferably have the same connection form as the second metal part 2B and the multilayer graphene 1. The connection form herein refers to a connection site, the connection area, or the like between the first metal part 2A or the second metal part 2B and the graphene sheet of the multilayer graphene 1.

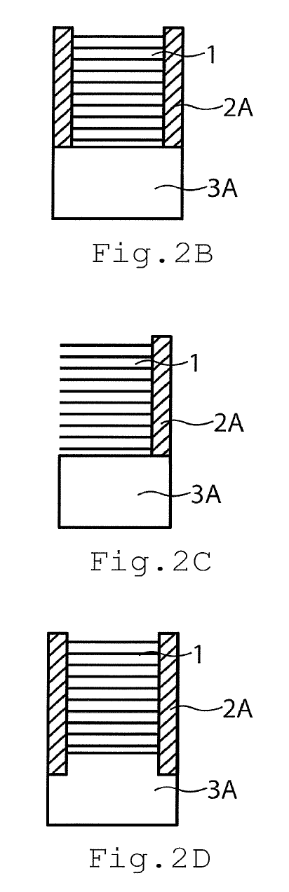

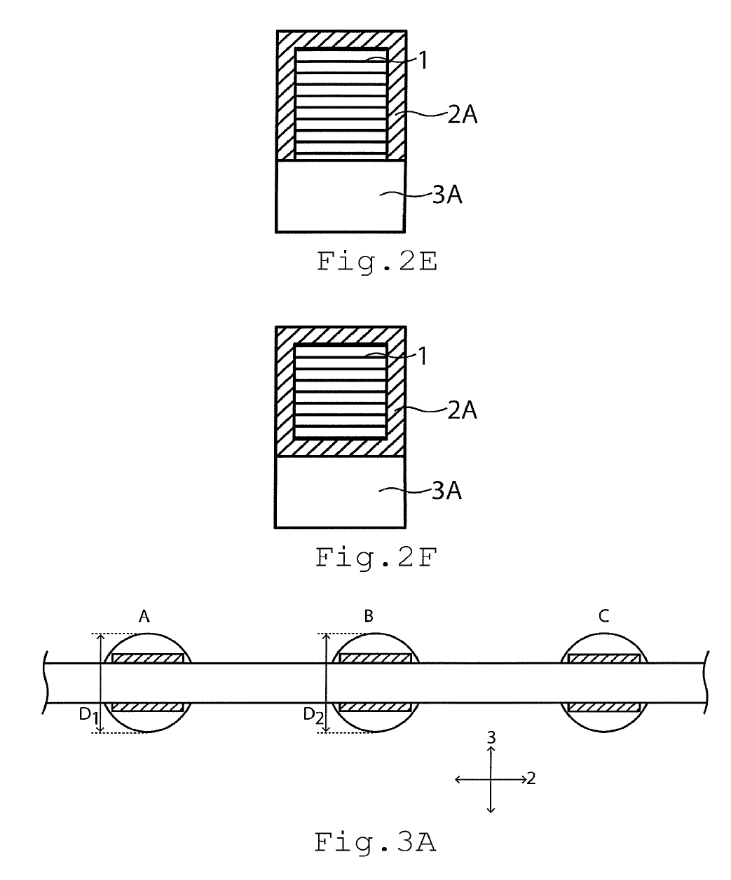

FIGS. 2A to 2F show cross-sectional pattern diagrams of wirings according to the embodiment, which represent multiple connection forms for the first metal part 2A and the multilayer graphene 1. FIGS. 2A to 2F also shows first conductive parts 3A. FIGS. 2A to 2F respectively illustrates six forms (A), (B), (C), (D), (E) and (F). In FIGS. 2A to 2F, the lateral direction is regarded as the third direction, and the longitudinal direction is regarded as the first direction. The vertical (bottom) direction is as shown in the drawing. While the first via wirings A are explained in FIGS. 2A to 2F, the same applies to the multilayer graphene 1, second metal part 2B, and second conductive part 3B of the second via wiring B.

In FIG. 2A, the first metal part 2A is in direct contact with the upper surface of the first conductive part 3A. The lowermost layer of graphene sheet is opposed to the upper surface of the first conductive part 3A. Some of the graphene sheets are in direct contact with the first metal part 2A from the lowermost layer side of the graphene sheets toward the upper surface side thereof. The first metal part 2A is in direct contact with parts of both edge sides for each of the graphene sheets. The graphene sheets in direct contact with the first metal part 2A are in contact with the first conductive part 3A via the first metal part 2A, and the graphene sheets without direct contact with the first metal part 2A are electrically connected between the graphene sheets.

In FIG. 2B, the first metal part 2A is indirect contact with the upper surface of the first conductive part 3A. The lowermost layer of graphene sheet is opposed to the upper surface of the first conductive part 3A. All of the graphene sheets are in direct contact with the first metal part 2A from the lowermost layer of graphene sheet toward the upper layer side. The first metal part 2A is in direct contact with parts of both edge sides for each of the graphene sheets. The graphene sheets in direct contact with the first metal part 2A are in contact with the first conductive part 3A via the first metal part 2A. As compared with the form in FIG. 2A, this form is excellent in contact property between the first metal part 2A and the multilayer graphene 1.

In FIG. 2C, the first metal part 2A is in direct contact with the upper surface of the first conductive part 3A. The lowermost layer of graphene sheet is opposed to the upper surface of the first conductive part 3A. All of the graphene sheets are in direct contact with the first metal part 2A from the lowermost layer side of graphene sheets toward the upper surface side. The first metal part 2A is in direct contact with a part of one edge side for each of the graphene sheets. The graphene sheets in direct contact with the first metal part 2A are in contact with the first conductive part 3A via the first metal part 2A. As compared with the form in FIG. 2B, this form can narrow the width of the entire wiring, because only one side of the graphene sheets is in contact.

In FIG. 2D, the first metal part 2A is partially embedded in the first conductive part 3A in direct contact with the first conductive part 3A. The lowermost layer of graphene sheet is opposed to the upper surface of the first conductive part 3A. All of the graphene sheets are in direct contact with the first metal part 2A from the lowermost layer side of graphene sheets toward the upper surface side. The first metal part 2A is in direct contact with parts of both edge sides for each of the graphene sheets. The graphene sheets in direct contact with the first metal part 2A are in contact with the first conductive part 3A via the first metal part 2A. As compared with the form in FIG. 2B, this form has an excellent contact property between the first metal part 2A and the first conductive part 3A, and has advantages such as improved reliability of wiring.

In FIG. 2E, the first metal part 2A is in direct contact with the upper surface of the first conductive part 3A. The lowermost layer of graphene sheet is opposed to the upper surface of the first conductive part 3A. All of the graphene sheets are in direct contact with the first metal part 2A from the lowermost layer side of graphene sheets toward the upper surface side. Furthermore, the first metal part 2A is disposed to be opposed to the uppermost surface side of the graphene sheets. The first metal part 2A is in direct contact with parts of both edge sides for each of the graphene sheets. The graphene sheets in direct contact with the first metal part 2A are in contact with the first conductive part 3A via the first metal part 2A. The first metal part 2A in direct contact with the both edge sides of the graphene sheets and the first metal part 2A opposed to the uppermost surface side of the graphene sheets may be made of the same material and continuous without any interface, or may be made with the use of different types of materials. As compared with the form of FIG. 2B, this form has advantages such as improved reliability of wiring.

In FIG. 2F, the first metal part 2A is in direct contact with the upper surface of the first conductive part 3A. The lowermost layer of graphene sheet is opposed to the upper surface of the first conductive part 3A. The first metal part 2A is disposed between the lowermost layer of graphene sheet and the first conductive part 3A. The lowermost layer of graphene sheet is opposed to the upper surface of the first conductive part 3A and the first metal part 2A between the lowermost layer of graphene sheet and the first conductive part 3A. All of the graphene sheets are in direct contact with the first metal part 2A from the lowermost layer side of graphene sheets toward the upper surface side. Furthermore, the first metal part 2A is disposed to be opposed to the uppermost surface side of the graphene sheets. The first metal part 2A is in direct contact with parts of both edge sides for each of the graphene sheets. The graphene sheets in direct contact with the first metal part 2A are in contact with the first conductive part 3A via the first metal part 2A. The first metal part 2A indirect contact with the both edge sides of the graphene sheets and the first metal part 2A opposed to the uppermost surface side of the graphene sheets may be made of the same material and continuous without any interface, or may be made with the use of different types of materials. As compared with the form of FIG. 2B, this form has advantages such as improved reliability of wiring.

The metal part in direct contact with the multilayer graphene 1 is in contact with the lamination surface at the side surface of the multilayer graphene 1. The upper surface and bottom surface of the multilayer graphene 1 may also are in direct contact with the metal part, but this connection never include a form that the metal part penetrates the multilayer graphene 1 and the multilayer graphene is in contact (direct contact) with the metal part inside the multilayer graphene 1. In other words, the metal part is not in direct contact with the graphene sheets other than a part of the edge side of the graphene sheet of the multilayer graphene 1 in the third direction; apart of the edge side of the graphene sheet thereof in the third direction and the graphene sheet of the multilayer graphene 1 closer to the bottom layer side; or a part of the edge side of the graphene sheet thereof in the third direction, the graphene sheet of the multilayer graphene 1 closer to the uppermost layer side, and the graphene sheet of the multilayer graphene 1 closer to the bottom layer side. In the form of the metal part in contact with the inside of the multilayer graphene 1, there is a hole through the inside of the graphene sheet of the multilayer graphene 1, the hole is filled with the metal part, and the graphene sheets are connected by the metal part. When the graphene sheet is connected to the metal part at the open end of this hole, it is necessary to make the hole large in order to increase the connection area between the graphene sheet and the metal part to make the contact property favorable, but if the hole is made large, the volume of metal part will be larger than that of the graphene sheet in the cross section at the via part, resulting in conduction substantially through the metal part. This influence becomes significant in fine wiring such as 10 nm or less in wiring width. The wiring according to the embodiment is preferred in that the multilayer graphene 1 allows low-resistance and low-delay conductivity without being influenced by the connection area with the metal part.

The first metal part 2A in contact with the multilayer graphene 1 is electrically connected to the first conductive part 3A, and the second metal part 2B in contact with the multilayer graphene 1 is in contact with the second conductive part 3B. Through such connection, the first conductive part 3A is in electrical contact with the second conductive part 3B via the first metal part 2A, the multilayer graphene 1 and the second metal part 2B.

The first metal part 2A and the second metal part 2B are not particularly limited as long as the parts include a metal. Among metals, from the viewpoint of the contact property between the graphene sheet and the metal part, it is preferable to include any one or more metals of Ti, Ta, and W which form conductive carbide at the interface between the graphene sheet and the metal part. It is preferable to include a carbide containing the metal included in the metal part between the graphene sheet and the first metal part 2A or the second metal part 2B, from the viewpoint of making favorable contact between the graphene sheet and the metal part. Such a carbide is preferably a carbide of any one or more metals selected from the group consisting of: Ti, Ta and W. In addition, the first metal part 2A and the second metal part 2B preferably contain any one or more metals selected from the group consisting of: Co, Ni, Pd and Ru that have a catalytic action. The first metal part 2A and the second metal part 2B preferably contain a metal that has a catalytic function, from the viewpoint of making a carbide more likely to be formed by the catalytic action. Therefore, the first metal part 2A and the second metal part 2B preferably contain any one or more metals selected from the group consisting of: Ti, Ta, W, Co, Ni, Pd and Ru.

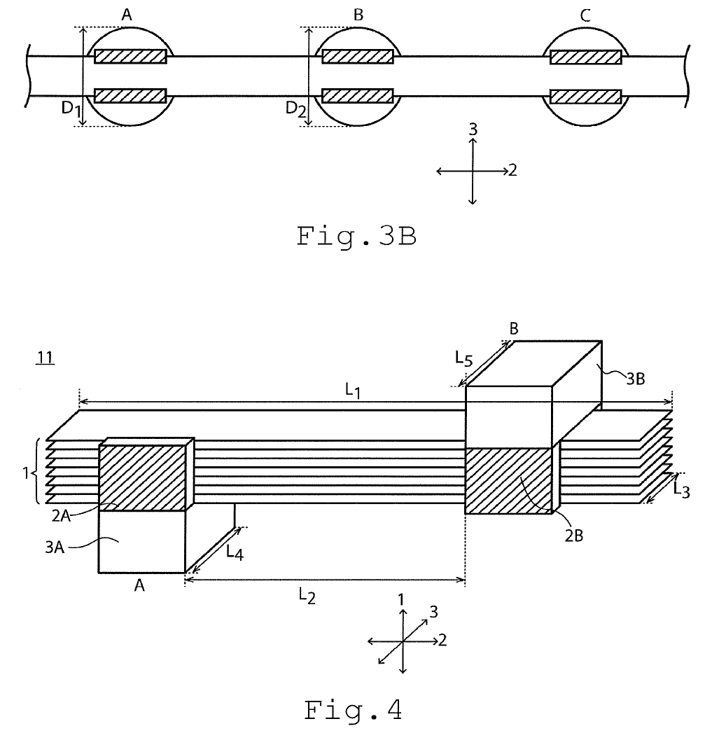

Next, advantages of the continuously connected multilayer graphene 1 according to the embodiment will be described with reference to top pattern diagrams of wirings according to the embodiment in FIGS. 3A and 3B. FIG. 3A shows a top view of a wiring including three via wirings as viewed from the first direction. The third via wiring C also has the same structure as the first via wiring A and the second via wiring B. In the wiring according to the embodiment, since all of the first, second and third via wirings are connected by the continuous multilayer graphene 1, electric conduction is achieved through the multilayer graphene 1 all between the first via wiring A and the second via wiring B, between the second via wiring B and the third via wiring C, and between the first via wiring A and the third via wiring C. In this regard, for example, if the second via wiring B has such a structure including the metal part as to divide the multilayer graphene 1, the conduction between the first via wiring A and the third via wiring C is achieved through the metal part that divides the multilayer graphene 1 at the second via wiring part. Then, the resistance between the first via wiring A and the third via wiring C is affected because the metal part that divides the multilayer graphene 1 has an influence on the conduction between the first via wiring A and the third via wiring C. The structure according to the embodiment allows electric conduction through the multilayer graphene 1 between all of the illustrated via wirings, which is preferable from the viewpoint of lowering the resistance and shortening signal delays in any of the zones.

FIG. 3B shows a pattern diagram of a modification example of FIG. 3A. The graphene sheet of the multilayer graphene 1 of FIG. 3B has a depressed shape, for example, at a connection part to the first via wiring A, where the first metal part 2A is partially embedded. Also in the second via wiring B and the third via wiring C, the metal part is partially embedded in the same manner. In the both configurations in FIGS. 3A and 3B, the edge side of the graphene sheet of the multilayer graphene 1 partially is in direct contact with the metal part, and the inside of the graphene sheet is not in direct contact with the metal part.

The edge side of the graphene sheet of the multilayer graphene 1 partially is in direct contact with the first metal part 2A. The length of the first metal part 2A in the second direction, which is the length in direct contact, is preferably 5 nm or more and 50 nm or less. If the length is excessively small, the density of a current flowing through the first metal part 2A is increased, and the connection stability and the contact property are not superior. Alternatively, if the length is excessively large, the space between the wirings becomes narrow, which is not preferable from the viewpoint of line capacitance. It is to be noted that although the length of the first metal part 2A in the second direction may be smaller or larger than the length of the first conductive part 3A in the second direction, the length is preferably smaller than the length of the first conductive part 3A in the second direction. Similarly, the length of the second metal part 2B in the second direction, which is the length in which the edge side of the graphene sheet of the multilayer graphene 1 partially is in direct contact with the second metal part 2B, is preferably 5 nm or more and 50 nm or less. Although the length of the second metal part 2B in the second direction may be smaller or larger than the length of the second conductive part 3B in the second direction, the length is preferably smaller than the length of the second conductive part 3B in the second direction.

The lengths in the third direction, which are the thicknesses of the first metal part 2A and the second metal part 2B, are preferably 5 nm or more and 10 nm or less. If the first metal part 2A and the second metal part 2B are excessively small in thickness, the contact properties with the first conductive part 3A and the second conductive part 3B are deteriorated. In addition, if the first metal part 2A and the second metal part 2B are excessively large in thickness, the entire wiring is increased in width, which is not preferable from the viewpoint of miniaturization.

The length L1 of the multilayer graphene 1 in the second direction is preferably larger than the distance L2 between the first metal part 2A and the second metal part 2B. The fact that the length L1 of the multilayer graphene 1 in the second direction is larger than the distance L2 between the first metal part 2A and the second metal part 2B indicates that the continuous multilayer graphene 1 is provided without making the multilayer graphene 1 discontinuous between the first via wiring A and the second via wiring B. In the wiring, there are many via wirings besides the illustrated via wiring, and these via wirings and the multilayer graphene 1 are preferably connected without making the multilayer graphene 1 discontinuous. In addition, since the electrical signal transmitted through the multilayer graphene 1 is preferred from the viewpoint of shortening the signal delay as the distance through the metal parts without discontinuity is longer, the length L1 of the multilayer graphene 1 is more preferably larger. Since the effect becomes remarkable as the multilayer graphene 1 is longer, the length L2 of the multilayer graphene 1 in the second direction is preferably longer. Therefore, the length L1 of the multilayer graphene 1 in the second direction is more preferably twice or more as large as the distance L2 between the first metal part 2A and the second metal part 2B, and the length L1 of the multilayer graphene 1 in the second direction is even more preferably ten times or more as large as the distance L2 between the first metal part 2A and the second metal part 2B.

The first conductive part 3A and the second conductive part 3B are electrically connected to both an active element such as a semiconductor element (not shown) or a passive element such as a resistor, and the multilayer graphene 1. The conductive parts are not particularly limited as long as the parts include a metal. The first conductive part 3A and the second conductive part 3B preferably include, for example, any one or more metals selected from the group consisting of: Al, Cu, Ti, Ta, W, Ag, Au, and the like, or polycrystalline Si or carbon nanotubes. The carbon nanotube may have a single layer or multiple layers. The carbon nanotube extends in the first direction, and the first direction is regarded as the longitudinal direction. The carbon nanotuhe is electrically connected to the first metal part 2A or the second metal part 2B. There is preferably a plurality of carbon nanotubes. There is preferably a plurality of carbon nanotubes extending in the first direction, which are arranged side by side in the second direction and the third direction.

The first conductive part 3A is electrically connected to the first metal part 2A. The first conductive part 3A is preferably located immediately below the first metal part 2A. In other words, the first conductive part 3A and the first metal part 2A have surfaces opposed in the first direction. Since the first conductive part 3A is located immediately below the first metal part 2A, the first metal part 2A in direct contact with the multilayer graphene 1 is in direct contact or indirect contact with the first conductive part 3A to form an electrically favorable contact. Thus, the wiring is provided where the multilayer graphene 1 and the first conductive part 3A are connected to be low in resistance. It is to be noted that the term “immediately below” represents the location immediately below when the wiring 10 is viewed from the direction in FIG. 1.

Likewise, the second conductive part 3B is electrically connected to the second metal part 2B. The second conductive part 3B is preferably located immediately below the second metal part 2B. In other words, the second conductive part 3B and the second metal part 2B have surfaces opposed in the first direction. Since the second conductive part 3B is located immediately below the second metal part 2B, the second metal part 2B in direct contact with the multilayer graphene 1 has direct connection or indirect connection with the second conductive part 3B to form an electrically favorable contact. Thus, the wiring is provided where the multilayer graphene 1 and the second conductive part 3B are connected to be low in resistance. Even when there is a conductive layer between the first metal part 2A and the first conductive part 3A and between the second metal part 2B and the second conductive part 3B, favorable contacts are similarly formed with the conductive layers interposed therebetween.

Another conductive layer may be provided either one or both between the first metal part 2A and the first conductive part 3A and between the second metal part 2B and the second conductive part 3B. When there is a conductive layer, the first metal part 2A is directly and electrically connected to either one or both of the conductive layer and the first conductive part 3A. When there is a conductive layer, the second metal part 2B is directly and electrically connected to either one or both of the conductive layer and the second conductive part 3B.

The conductive layer may be, for example, a catalyst metal layer that functions as a catalyst in the growth of graphene sheets for the multilayer graphene 1, a catalyst base layer for use as a base layer for the catalyst metal layer, and the like. The conductive layer may be a single layer or a laminated layer. The conductive layer as a catalytic metal layer preferably has a metal containing any of the group consisting of Co, Ni, Fe, Ru Cu, and the like the like, or an alloy containing any one of the group consisting of: Co, Ni, Fe, Ru, Cu, and the like. In addition, the conductive layer as a base layer preferably has a conductive nitride or a conductive oxide containing any metal of the group consisting of: Ti, Ta, Ru, W, and the like.

The shapes of the first conductive part 3A and the second conductive part 3B are, for example, prisms, cylinders, prismatic columns (truncated pyramids), cylindrical columns (truncated cones), but are not particularly limited.

From the viewpoint of the contact property between the first metal part 2A and the first conductive part 3A, the length L3 of the multilayer graphene 1 in the third direction is preferably smaller than the length L4 of the first conductive part 3A in the third direction. Likewise, the length L3 of the multilayer graphene 1 in the third direction is preferably smaller than the length L5 of the second conductive part 3B in the third direction.

From the viewpoint of the contact property between the first metal part 2A and the first conductive part 3A, the length L3 of the multilayer graphene 1 in the third direction is shorter than the circumscribed circle diameter D1 of the surface of the first conductive part 3A, opposed to the multilayer graphene 1. Likewise, the length L3 of the multilayer graphene 1 in the third direction is preferably smaller than the circumscribed circle diameter D2 of the surface opposed to the multilayer graphene 1.

In the embodiment, although graphene has been described as an example, a hexagonal boron nitride may be adopted which is a sheet-like compound just like the graphene sheet, for example.

### Embodiment 2

A wiring according to Embodiment 2 is a modification example of the wiring according to Embodiment 1. FIG. 4 shows therein a perspective pattern diagram of the wiring according to Embodiment 2. The difference between the wiring 10 shown in FIG. 1 and the wiring 11 shown in FIG. 4 is that the first via wiring A is located on the bottom layer side of the multilayer graphene 1, whereas the second via wiring is located on the uppermost layer side of the multilayer graphene 1, such that the first metal part 2A and the second metal part 2B is in direct contact with all layers of the graphene sheets of the multilayer graphene 1.

The wiring according to this embodiment also has the multilayer graphene 1 connected to the via wirings without discontinuity, thus resulting in a wiring which is low in resistance and small in signal delay.

### Embodiment 3

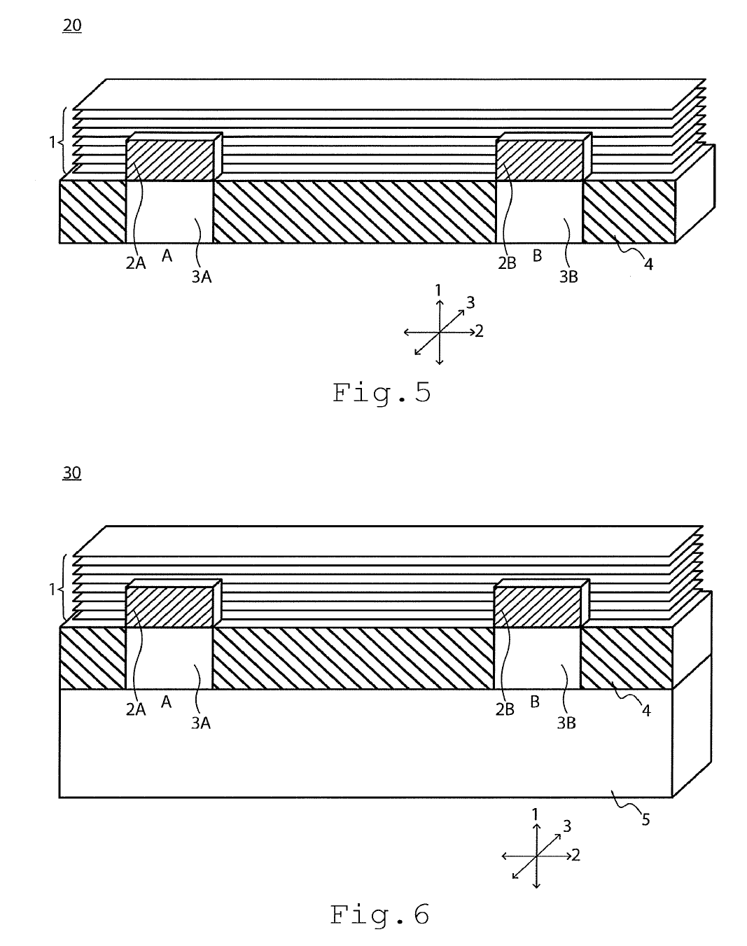

A wiring according to Embodiment 3 is a modification example of the wiring 10 according to Embodiment 1. FIG. 5 shows therein a perspective pattern diagram of a wiring 20 according to Embodiment 3. The wiring 20 in FIG. 5 further includes an insulating layer 4 in relation to the wiring 11 according to Embodiment 2, and the insulating layer 4 has therein the first conductive part 3A and the second conductive part 3B. The multilayer graphene 1 is disposed on the insulating layer 4. The insulating layer 4 and the multilayer graphene 1 are laminated.

The insulating layer 4 is preferably a film containing at least one selected from the group consisting of: SiOC, SiCN and SiO₂. Further, the insulating layer 4 is more preferably any one selected from the group consisting of SiOC, SiCN, SiO₂, and the like. The thickness of the insulating layer 4 is, for example, 1 μm or more and 10 μm or less.

Preferably, there is a plurality of wirings according to Embodiment 3 arranged in parallel on the insulating layer 4, for example. Such a wiring is a low-resistance and low-delay wiring, and it is thus preferable to use the wiring as a bit line of a storage device which transmits signals at high speed, for example.

### Embodiment 4

According to Embodiment 4, the wiring according to the third embodiment is used for a semiconductor device. FIG. 6 shows a perspective pattern diagram of a semiconductor device 30 according to Embodiment 4. The semiconductor device 30 in FIG. 6 further includes a substrate 5 with a semiconductor integrated circuit and the like in relation to the wiring 20 according to Embodiment 3.

Hereinafter, a method for manufacturing a wiring according to an embodiment will be exemplified by taking, as an example, a method for manufacturing a semiconductor device according to Embodiment 4.

The substrate 5 with a semiconductor integrated circuit and the like formed includes a lower wiring layer (not shown). Then, the insulating layer 4 is formed which uses a low dielectric constant insulating layer such as SiOC, for example. In this regard, the lower wiring layer may have a structure of multiple different conductive materials laminated, or may have graphene or a metal composed of an element such as Cu. Further, the insulating layer 4 may have a laminated structure such as an etching stop film that uses an insulating layer such as SiCN, for example. Next, via holes for conductive parts are formed through the insulating layer 4 to the lower wiring layer by, for example, dry etching with the use of a fluorine-based gas. Then, the first conductive part 3A and the second conductive part 3B are formed.

In a case where the first conductive part 3A and the second conductive part 3B have carbon nanotubes, the carbon nanotubes can be grown by a thermal CVD (Chemical Vapor Deposition) method or a plasma CVD method with the use of a catalyst metal film, for example. Alternatively, in a case where the first conductive part 3A and the second conductive part 3B have metals composed of an element such as Cu, via wirings can be formed by a plating method or a sputtering method. In any case, planarization polishing can be performed by chemical mechanical polishing (CMP).

Next, on the insulating layer 4, the first conductive part 3A, and the second conductive part 3B, multilayer graphene is grown over the entire substrate surface. In this regard, a catalyst metal film and a base layer under the catalyst metal film may be inserted, which may have a structure of multiple different conductive materials laminated, and desirably have a function as a co-catalyst for graphene growth. In addition, the catalyst metal film is desirably a continuous film for the sake of large-area graphene growth. For graphene growth, for example, a thermal CVD method and a plasma CVD method are available. In the case of using the plasma CVD method, the temperature of the substrate is increased to, for example, 600° C. in a reaction furnace, a hydrocarbon-based gas such as a methane gas is introduced as a raw material gas, whereas hydrogen is introduced as a carrier gas, and the methane gas is excited/discharged by microwave to turn the material gas into plasma, thereby causing multilayer graphene to grow on the insulating layer 4, the first conductive part 3A, and the second conductive part 3B. Further, multilayer graphene can also be formed by growing multilayer graphene on another substrate with the catalyst metal film formed, peeling the graphene from the catalyst metal film, and transferring the graphene onto the insulating layer 4, the first conductive part 3A, and the second conductive part 3B.

Next, for example, an etching mask such as SiO₂ or a resist mask is formed on the multilayer graphene, and processed into a wiring shape by, for example, dry etching with the use of an oxygen-based gas. Thereafter, this substrate may be heated to about 400° C. by a plasma CVD method or the like. Graphene edges may be treated by introducing a gas containing hydrogen as a raw material gas, and exciting/discharging hydrogen gas, for example, at a high frequency.

Next, a metal to serve as metal parts are formed on the entire surfaces of the multilayer graphene 1, the first conductive part 3A, the second conductive part 3B, and the insulating layer 4, and subjected to planarization polishing by CMP, for example, an etching mask such as SiO₂ or a resist mask is formed on the multilayer graphene 1 and the insulating layer 4, and the unnecessary metal is removed to form the first metal part 2A and the second metal part 2B. In this regard, the increased temperature of the substrate in the reaction furnace, for example, causes the reaction to proceed at the interfaces between the first metal part 2A and the second metal part 2B and the graphene sheets of the multilayer graphene 1, and the contact resistance is expected to be reduced.

### Embodiment 5

Embodiment 5 relates to a semiconductor device that uses the wiring according to the embodiment. The type of the semiconductor device is not particularly limited, and the wiring may be adopted for semiconductor computing devices such as LSI (Large-Scale Integration), NAND-type flash memory semiconductor storage devices, SoC (System on Chip) including the devices, and the like.

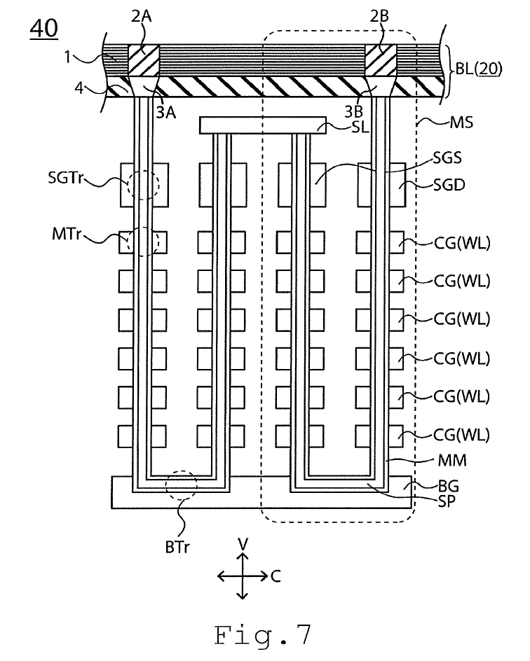

FIG. 7 shows a cross-sectional pattern diagram of a three-dimensional NAND-type flash memory as an example of a semiconductor device (semiconductor storage device) that uses the wiring according to the embodiment. The three-dimensional NAND-type flash memory shown in FIG. 7 includes a substrate 6, a back gate BG, a control gate CG (word line WL), a source-side selection gate SGS (selection gate SG), a drain-side selection gate SGD (selection gate SG), a source line SL, a silicon column SP, a memory film MM and a bit line BL. In FIG. 7, six layers of control gates CG are stacked in the stacking direction V, but the embodiment is not limited to this example. In FIG. 7, a memory cell array is disposed on the substrate 6.

In the semiconductor device 40 according to the embodiment, the wiring 20 according to the embodiment is adopted for the bit line BL. The multilayer graphene 1 of the wiring 20 is electrically connected to the memory film MM. Therefore, the bit line BL serves as a low-resistance wiring, which contributes to an improvement in signal read-out speed.

Columns extending from the bit line BL to the back gate BG are arranged side by side in a column direction C, and in a row direction R perpendicular to the cross section in FIG. 7. The columns extending from the bit line BL to the back gate BG each include a central silicon column SP and a memory film MM surrounding the outside of the silicon column SP. The silicon columns SP and the memory films MM are connected in the back gate BG to take a U-shaped form.

Multiple control gates CG and selection gates SG extending in the row direction R are arranged in a row in the column direction C. In addition, multiple bit lines BL extending in the column direction C are arranged side by side in the row direction R.

The silicon columns SP, the memory films MM around the silicon columns SP, and the various types of gates (control gates CG, selection gates SG, back gate BG) constitute memory cell transistors MTr as memory cells, selection gate transistors SGTr (drain-side selection gate transistors SGDTr and source-side selection gate transistors SGSTr), and back gate transistors BTr. The silicon columns SP functions as channels and source/drain diffusion layers for the memory cell transistors MTr, the selection gate transistors SGTr, and the back gate transistors BTr.

The current paths through the plurality of memory cell transistors MTr and the back gate transistor BTr are connected in series between the drain-side selection gate transistor SGDTr and the source-side selection gate transistor SGSTr. Thus, memory strings MS are configured.

The source line SL extends in the row direction R while ends of U-shaped memory strings MS adjacent in the column direction C are connected to each other. The bit line BL extends in the column direction C while the memory strings MS aligned in the column direction C are connected to each other.

In addition, contacts are connected respectively to ends of the source line SL, the back gate BG, the source-side selection gates SGS, and the drain-side selection gates SGD in the row direction R. Contacts are connected to respective stages of the plurality of word lines WL. These contacts are each connected to wiring (any not shown).

The memory cell array shown in FIG. 7 has various types of transistors such as memory cell transistors MTr arranged three-dimensionally in a matrix. The memory cell array includes an assembly of these various types of transistors.

In the embodiment, the method for storage in the memory cells may be a binary storage method, a multi-level storage method, or the like. The control of charge accumulation in the selected memory cell can write and erase data, and read out data according to the determination of the threshold voltage which varies depending on the charge accumulation amount.

In the above embodiment, although an example of the memory string MS has been described which has a U-shaped form with the silicon column SP and memory films MM coupled, the embodiment is not limited thereto. For example, the memory string MS may be configured in an I-shaped form without any coupled part.

In the above embodiment, although the charge storage-type storage device has been described as an example, it is preferable to use the wiring according to the embodiment for bit lines of storage devices such as a resistance change-type storage device, a phase change-type storage device, and a magnetoresistive type storage device.

Here, some elements are expressed only by element symbols thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A wiring comprising:
a multilayer graphene including graphene sheets laminated in a first direction, the multilayer graphene extended in a second direction regarded as a longitudinal direction that intersects with the first direction;
a first metal part in direct contact with the multilayer graphene;
a second metal part spaced apart from the first metal part in the second direction, the second metal part indirect contact with the multilayer graphene;
a first conductive part disposed on the multilayer graphene in the first direction, and electrically connected to the multilayer graphene with the first metal part interposed therebetween; and
a second conductive part disposed on the multilayer graphene in the first direction, and electrically connected to the multilayer graphene with the second metal part interposed therebetween, wherein
the first conductive part and the second conductive part are electrically connected with the first metal part, the multilayer graphene, the second metal part interposed therebetween, and
a length L1 of the multilayer graphene in the second direction is larger than a length L2 between the first metal part and the second metal part.

2. The wiring according to claim 1, wherein
the first conductive part is in direct contact with the first metal part, and
the second conductive part is in direct contact with the second metal part.

3. The wiring according to claim 1, wherein the length L1 of the multilayer graphene in the second direction is twice or more as large as the length L2.

4. The wiring according to claim 1, wherein
a direction orthogonal to both of the first direction and the second direction is referred to as a third direction,
among the graphene sheets of the multilayer graphene, the graphene sheet located closest to the first conductive part in the third direction has a side edge in direct contact with the first metal part, and
among the graphene sheets of the multilayer graphene, the graphene sheet located closest to the second conductive part in the third direction has a side edge in direct contact with the second metal part.

5. The wiring according to claim 1, wherein
when the number of graphene sheets in the multilayer graphene laminated is n, side edges in the third direction from the graphene sheet located closest to the first conductive part to at least the n/2-th graphene sheet is in direct contact with the first metal part, and
side edges in the third direction from the graphene sheet located closest to the second conductive part to at least the n/2-th graphene sheet is partially in direct contact with the second metal part.

6. The wiring according to claim 1, wherein
a direction orthogonal to both the first direction and the second direction is referred as a third direction,
a length L3 of the multilayer graphene in the third direction is smaller than a length L4 of the first conductive part in the third direction, and
the length L3 of the multilayer graphene in the third direction is smaller than a length L5 of the second conductive part in the third direction.

7. The wiring according to claim 1, wherein
a direction orthogonal to both the first direction and the second direction is referred to as a third direction,
a length L3 of the multilayer graphene in the third direction is smaller than a circumscribed circle diameter D1 of the first conductive part, and
the length L3 of the multilayer graphene in the third direction is smaller than a circumscribed circle diameter D2 of the second conductive part.

8. The wiring according to claim 1, wherein
a direction orthogonal to both the first direction and the second direction is referred to as a third direction, and
a side edge of the graphene sheet of the multilayer graphene in the second direction comprises a zigzag edge.

9. The wiring according to claim 1, wherein
a direction orthogonal to both the first direction and the second direction is referred to as a third direction, and
a side edge of the graphene sheet of the multilayer graphene in the third direction comprises an armchair edge.

10. The wiring according to claim 1, wherein a length L3 of the multilayer graphene in the third direction is 10 nm or less.

11. The wiring according to claim 1, wherein further comprising an interlayer substance between graphene sheet layers of the multilayer graphene.

12. The wiring according to claim 1, wherein
the wiring further comprises an insulating layer,
the first conductive part and the second conductive part are located in the insulating layer, and
the multilayer graphene is disposed on the insulating layer.

13. A semiconductor device using the wiring according to claim 1.

14. The semiconductor device according to claim 13, wherein the semiconductor device is a NAND flash memory.

15. A NAND flash memory wherein the multilayer graphene of the wiring according to claim 1 is used for a bit line of the NAND flash memory.
